(19) United States
(12) Patent Application Publication
(10) Pub. No.: US 2009/0000743 A1
(43) Pub. Date: Jan. 1, 2009

(54) SUBSTRATE PROCESSING APPARATUS AND SHOWER HEAD

(75) Inventor: Hachishiro IIZUKA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/146,706

(22) Filed: Jun. 26, 2008

Related U.S. Application Data
(60) Provisional application No. 60/973,789, filed on Sep. 20, 2007.

(30) Foreign Application Priority Data
Jun. 27, 2007 (JP) 2007-168861

(51) Int. Cl. H01L 21/3065

(52) U.S. Cl. 156/345.34

(57) ABSTRACT

A substrate processing apparatus includes a shower head having a shower plate of which gas injection portion is formed by a two layer structure made of metal and ceramic. The shower head has an upper plate made of a metal and having a gas inlet hole; a lower plate made of a metal and having a plurality of gas through holes; a gas diffusion space formed between the upper plate and the lower plate; and a cover member made of ceramic and having a plurality of gas injection openings positioned to correspond to the gas through holes, for covering an entire bottom surface of the lower plate. The shower head further includes a plurality of thermally conductive members provided to connect the upper plate with the lower plate in the gas diffusion space for transferring heat generated by processing upward.

### FIELD OF THE INVENTION

The present invention relates to a substrate processing apparatus for performing a processing, e.g., plasma etching or the like, on a substrate such as a semiconductor wafer or the like, and a shower head used therefor.

### BACKGROUND OF THE INVENTION

For example, in a semiconductor device manufacturing process, a plasma etching process for performing plasma etching using a resist as a mask has been widely used in order to form a predetermined pattern in a specified layer formed on a semiconductor wafer, which is used as a substrate to be processed.

Although various apparatuses are used as the plasma etching apparatus for performing the plasma etching, there is mainly used a capacitively coupled parallel plate type plasma processing apparatus.

In the capacitively coupled parallel plate type plasma etching apparatus, a pair of parallel plate electrodes (an upper and a lower electrode) are disposed in a chamber, and a processing gas is introduced into the chamber. Further, a high frequency power is applied to one or both of the electrodes, so that a high frequency electric field is formed between the electrodes. The processing gas is converted into a plasma by the high frequency electric field, thereby performing plasma etching on a predetermined layer of a semiconductor wafer. To be specific, a susceptor for mounting thereon the semiconductor wafer serves as the lower electrode, and a shower head for supplying the processing gas in a shower shape serves as the upper electrode. By forming the high frequency electric field therebetween, the processing gas is converted into the plasma (e.g., Japanese Patent Laid-open Publication No. 2000-173993).

Meanwhile, in the capacitively coupled parallel plate plasma etching apparatus, in order to prevent metal contamination and protect the shower head from the plasma and damage, a metal plate having a bottom surface coated with ceramic or a metal plate having a bottom surface to which an insulating ceramic plate such as a quartz plate or the like is attached is used as a shower plate of the shower head.

The shower head of the plasma etching apparatus is heated by radiant heat from the mounting table that has been heated or by heat applied from the plasma. Meanwhile, a space for mixing or diffusing the processing gas is provided in the shower head, and this space serves as an insulating part. Therefore, the heat applied to the shower head is transferred only to a peripheral edge portion which does not include the space, without being sufficiently emitted. Accordingly, the temperature of the shower head tends to be increased.

If the temperature of the shower head increases, the shower plate made of metal and ceramic is thermally expanded and, thus, a plurality of gas injection openings formed in the shower plate are misaligned due to the difference in thermal expansion between the metal and the ceramic. The misalignment is severe especially in the peripheral edge portion of the shower head and, hence, gas may not be injected. Accordingly, etching uniformity and the like deteriorates.

The above problem occurs not only in a plasma etching apparatus but also in a substrate processing apparatus for performing a substrate processing by using a shower head having a shower plate of a two layer structure made of metal and ceramic.

### SUMMARY OF THE INVENTION

In view of the above, the present invention provides a substrate processing apparatus capable of performing uniform processing by using a shower head having a shower plate of which gas injection portion is formed by a two layer structure made of metal and ceramic, and also provides a shower head used for the substrate processing apparatus.

In accordance with a first aspect of the present invention, there is provided a substrate processing apparatus including a processing chamber accommodating therein a substrate to be processed; a mounting table disposed in the processing chamber, for mounting thereon the substrate to be processed; a shower head provided opposite to the mounting table, for injecting a processing gas into the processing chamber; a gas exhaust unit for exhausting an inside of the processing chamber; and a processing unit for performing a predetermined processing on the substrate to be processed in the processing chamber.

The shower head includes an upper plate made of a metal and having a gas inlet hole; a lower plate made of a metal and having a plurality of gas through holes; a gas diffusion space formed between the upper plate and the lower plate; a cover member made of ceramic and having a plurality of gas injection openings positioned to correspond to the gas through holes, for covering a bottom surface of the lower plate; and a plurality of thermally conductive members provided to connect the upper plate with the lower plate in the gas diffusion space, for transferring heat generated by the processing of the processing unit upward.

In accordance with a second aspect of the present invention, there is provided a substrate processing apparatus including a processing chamber accommodating therein a substrate to be processed; a mounting table disposed in the processing chamber, for mounting thereon the substrate to be processed; a shower head provided at opposite to the mounting table, for injecting a processing gas into the processing chamber; a gas exhaust unit for exhausting an inside of the processing chamber; and a processing unit for performing a predetermined processing on the substrate to be processed in the processing chamber.

The shower head includes an upper plate made of a metal and having a gas inlet hole; a lower plate made of a metal and having a plurality of gas through holes; a middle plate provided between the upper plate and the lower plate and having a plurality of gas through holes; a first gas diffusion space provided between the upper plate and the middle plate; a second gas diffusion space provided between the middle plate and the lower plate; a cover member made of ceramic and having a plurality of gas injection openings positioned to correspond to the gas through holes, for covering a bottom surface of the lower plate; and a plurality of thermally conductive members provided to connect the upper plate with the middle plate in the first gas diffusion space and to connect the middle plate with the lower plate in the second gas diffusion space, for transferring heat generated by the processing of the processing unit upward.

In accordance with a third aspect of the present invention, there is provided a shower head provided opposite to a mounting table which mounts thereon a substrate to be processed in a processing chamber, for injecting a processing gas into the processing chamber.

The shower head includes an upper plate made of a metal and having a gas inlet hole; a lower plate made of a metal and having a plurality of gas through holes; a gas diffusion space formed between the upper plate and the lower plate; a cover member made of ceramic and having a plurality of gas injection openings positioned to correspond to the gas through holes, for covering a bottom surface of the lower plate; and a plurality of thermally conductive members provided to connect the upper plate with the lower plate in the gas diffusion space, for transferring heat generated by processing performed in the processing chamber upward.

In accordance with fourth aspect of the present invention, there is provided a shower head provided opposite to a mounting table which mounts thereon a substrate to be processed in a processing chamber, for injecting a processing gas when performing a predetermined processing in the processing chamber.

The shower head includes an upper plate made of a metal and having a gas inlet hole; a lower plate made of a metal and having a plurality of gas through holes; a middle plate provided between the upper plate and the lower plate, having a plurality of gas through holes; a first gas diffusion space provided between the upper plate and the lower plate; a second gas diffusion space provided between the middle plate and the lower plate; a cover member made of ceramic and having a plurality of gas injection openings positioned to correspond to the gas through holes, for covering a bottom surface of the lower plate; and a plurality of thermally conductive members provided to connect the upper plate with the middle plate in the first gas diffusion space and to connect the middle plate with the lower plate in the second gas diffusion space, for transferring heat generated by the processing performed in the processing chamber upward.

In the first to fourth aspects, a contact portion between the lower plate and the cover member is preferably formed in a convexoconcave shape. Further, the thermally conductive members preferably have a cylindrical shape. Furthermore, the thermally conductive members may have a diameter in a range from about 2 to 12 mm.

In the first and second aspects, the processing unit may perform plasma processing on the substrate to be processed by generating a plasma in the processing chamber. The processing unit may form a high frequency electric field between the mounting table and the shower head, and a plasma is generated by the high frequency electric field.

In the second and fourth aspects, the thermally conductive members provided in the first gas diffusion space and the thermally conductive members provided in the second diffusion space are preferably arranged to correspond to each other.

In the third and fourth aspects, the processing may be plasma processing which is performed on a substrate to be processed by generating a plasma in the processing chamber.

In accordance with the present invention, in the shower head including an upper plate made of a metal and having a gas inlet; a lower plate made of a metal and having a plurality of gas through holes; a gas diffusion space formed between the upper plate and the lower plate; and a cover member made of ceramics and having a plurality of gas injection openings positioned to correspond to the gas through holes, for covering a bottom surface of the lower plate, since a plurality of thermally conductive members is provided to connect the upper plate with the lower plate in the gas diffusion space, for transferring heat generated by processing of the processing unit upward, the heat applied to the lower plate and the cover member can be quickly emitted by the thermally conductive members. Accordingly, it is possible to suppress the increase in the temperatures of the lower plate and the cover member and the temperature gradient, thereby reducing the misalignment of the gas through holes of the lower plate and the gas injection openings of the cover member due to the thermal expansion difference therebetween.

### BRIEF DESCRIPTION OF THE DRAWINGS

The objects and features of the present invention will become apparent from the following description of embodiments, given in conjunction with the accompanying drawings, in which:

FIG. 1 shows a cross sectional view of a plasma etching apparatus in accordance with an embodiment of the present invention;

FIG. 2 describes an enlarged cross sectional view of a shower head used in the plasma etching apparatus in FIG. 1;

FIG. 3 provides an enlarged cross sectional view of principal parts of the shower head used in the plasma etching apparatus in FIG. 1;

FIG. 4 presents a diagram for explaining effects of a convexoconcave shape formed between a cover member and a lower plate of the shower head in FIGS. 2 and 3;

FIG. 5 represents a diagram showing an arrangement relationship between gas through holes and a thermally conductive member in the shower head;

FIGS. 6A to 6C are diagrams illustrating misalignment of openings due to a thermal expansion difference between a lower plate and a cover member of a conventional shower head and heat transfer status therein; and

FIG. 7 offers a diagram for explaining heat transfer status in the shower head in accordance with the embodiment of the present invention.

### DETAILED DESCRIPTION OF THE EMBODIMENT

Embodiments of the present invention will be described with reference to the accompanying drawings which form a part hereof.

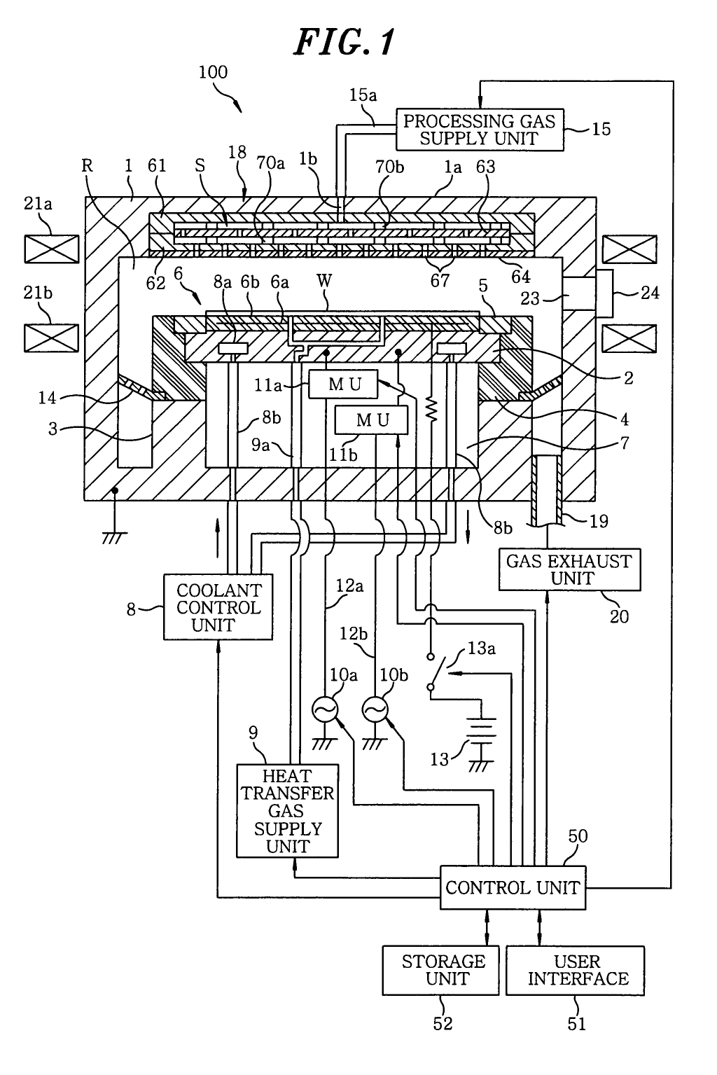

FIG. 1 is a cross sectional view of a plasma etching apparatus in accordance with an embodiment of the present invention.

A plasma etching apparatus 100 has a substantially cylindrical airtight chamber 1. The chamber 1 has a main body made of a metal, e.g., aluminum or the like, and an inner surface thereof is coated with an insulating film, such as an oxidized film, or a film made of insulating ceramic such as Y₂O₃ or the like (e.g., a thermally sprayed film). The chamber 1 is DC-grounded.

A supporting table 2 for horizontally supporting a wafer W as a substrate to be processed is provided in the chamber 1, and serves as a lower electrode. The supporting table 2 is made of aluminum of which surface is oxidized. An annular support 3 projects from a bottom wall of the chamber 1 to correspond to a periphery of the supporting table 2, and an annular insulating member 4 is provided on the support 3. An outer peripheral portion of the supporting table 2 is supported via the insulating member 4. Provided on an outer periphery of the supporting table 2 is a focus ring 5 made of a conductive material, e.g., Si, SiC or the like. A conical-shaped exhaust ring 14 is provided between a lower portion of the insulating member 4 and a peripheral wall of the chamber 1. The exhaust ring 14 has a function of passing a processing gas therethrough to a gas exhaust line 19 and defining a plasma generation region. Moreover, a cavity 7 is formed between the supporting table 2 and the bottom wall of the chamber 1.

Provided on a surface of the supporting table 2 is an electrostatic chuck 6 for electrostatically attracting the wafer W thereon. The electrostatic chuck 6 has a configuration in which an electrode 6a is embedded in an insulator 6b. A DC power supply 13 is connected to the electrode 6a via a switch 13a. Further, by applying a voltage from the DC power supply 13 to the electrode 6a, the semiconductor wafer W is attracted by an electrostatic force, e.g., a Coulomb force.

A coolant channel 8a is formed in the supporting table 2, and is connected to a coolant line 8b. A suitable coolant is supplied and circulated within the coolant channel 8a via the coolant line 8b by control of a coolant control unit 8. Accordingly, the supporting table 2 can be controlled to a suitable temperature. Further, a thermally conductive gas line 9a for supplying a thermally conductive gas, e.g., He gas, between a top surface of the electrostatic chuck 6 and a backside of the wafer W is provided, so that the thermally conductive gas is supplied from a thermally conductive gas supply unit 9 to the backside of the wafer W via the thermally conductive gas line 9a. Therefore, even when the interior of the chamber 1 is exhausted and maintained in a vacuum state, cold heat of the coolant circulated in the coolant channel 8a is efficiently transferred to the wafer W, thereby improving the temperature control of the wafer W.

Power feed lines 12a and 12b for supplying a high frequency power are connected to a substantially central portion of the supporting table 2. The power feed line 12a is connected through a matching unit (MU) 11a to a high frequency power supply 10a, and the power feed line 12b is connected through a matching unit (MU) 11b to a high frequency power supply 10b. A high frequency power for generating a plasma is supplied from the high frequency power supply 10a, and a high frequency power supply for attracting ions in a plasma is supplied from the high frequency power supply 10b.

Meanwhile, a shower head 18 for injecting a processing gas to be used in etching in a shower shape is disposed opposite to the supporting table 2. The shower head 18 serves as the upper electrode, and is inserted in a ceiling wall portion of the chamber 1. A structure of the shower head 18 will be described in detail later.

The shower head 18 as the upper electrode is grounded via the chamber 1, and forms a pair of parallel plate electrodes together with the supporting table 2 serving as the lower electrode to which a high frequency power is supplied. Moreover, the supporting table 2, which is the lower electrode, functions as a cathode electrode, and the shower head 18, which is the grounded upper electrode, functions as an anode electrode. A plasma generation region R is formed between the supporting table 2 as the cathode electrode and the upper electrode 18 as the anode electrode, and the region R also includes an area above the gas exhausting ring 14 outside the insulating member 4.

As for the processing gas for etching, there can be employed various conventional gases. For example, it is possible to use gas containing a halogen element such as fluorocarbon gas (C_{X}F_{Y}) or hydrofluorocarbon gas (CₚH_{q}Fᵣ). N₂ gas, O₂ gas, or a rare gas such as Ar, He or the like may be added to the processing gas. Further, in ashing, there can be used, e.g., O₂ gas or the like as the processing gas.

The processing gas is supplied form a processing gas supply source 15 to the shower head 18 via a gas supply line 15a and the gas inlet hole 1b formed in the ceiling portion 1a of the chamber 1. Then, the processing gas is injected from the shower head 18 in a shower shape to be used for etching a film formed on the wafer W.

The gas exhaust line 19 is connected to the bottom wall of the chamber 1 and also connected to a gas exhaust unit 20 including a vacuum pump or the like. By operating the vacuum pump of the gas exhaust unit 20, a pressure inside the chamber 1 can be reduced to a predetermined vacuum level. A gate valve 24 for opening/closing a loading/unloading port 23 of the wafer W is provided at the sidewall of the chamber 1.

Meanwhile, two ring magnets 21a and 21b are respectively arranged concentrically around the chamber 1 at positions above and below the loading/unloading port 23 of the chamber 1. Accordingly, a magnetic field is formed around the processing space provided between the supporting table 2 and the shower head 18. The ring magnets 21a and 21b are rotatable by a rotation mechanism (not shown).

In each of the ring magnets 21a and 21b, a plurality of segment magnets formed of permanent magnets are disposed in a ring shape in a multi-pole state. Thus, magnetic force lines are formed between adjacent segment magnets, and a magnetic field is formed only at the peripheral portion of the processing space. Therefore, substantially no magnetic field is formed at the position where the wafer is placed. Accordingly, it is possible to obtain a suitable effect of confining a plasma.

The respective components of the plasma etching apparatus 100 are connected to a control unit (process controller) 50 and controlled thereby. To be specific, the control unit 50 controls the coolant control unit 8, the thermally conductive gas supply unit 9, the gas exhaust unit 20, the switch 13a of the DC power supply 13 for the electrostatic chuck 6, the high frequency power supplies 10a and 10b, the matching unit 11 and the like.

The control unit 50 is connected to a user interface 51 including a keyboard, a display and the like. A process operator uses the keyboard for inputting commands to operate the plasma etching apparatus 100, and the display is used for showing the operational status of the plasma etching apparatus 100.

Further, the process controller 50 is connected to a storage unit 52 which stores therein recipes including control programs for implementing various processes in the plasma etching apparatus 100 under the control of the control unit 50, and programs for executing processes in the respective components of the plasma etching apparatus 100 according to processing condition data and the like. The recipes can be stored in a hard disk or a semiconductor memory, or stored in a portable storage medium, such as CD-ROM, DVD or the like, to be set at a specified position in the storage medium 52.

If necessary, the control unit 50 executes a recipe read from the storage unit 52 in response to instructions from the user interface 51, thereby implementing a required process in the plasma etching apparatus 100 under the control of the control unit 50.

Hereinafter, the shower head 18 will be described in detail.

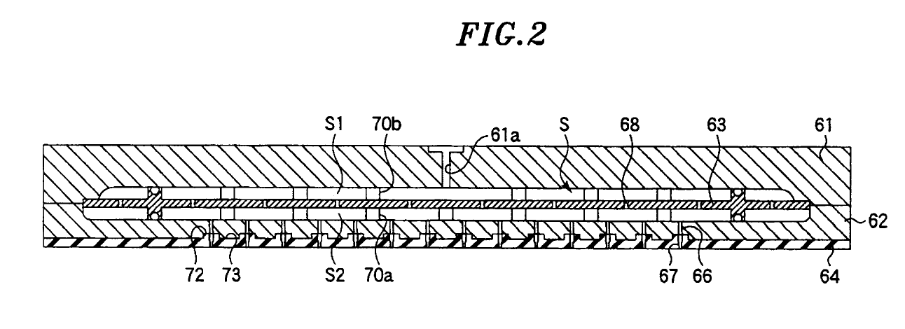

FIG. 2 describes an enlarged cross sectional view of the shower head. As shown in FIG. 2, the shower head 18 includes an upper plate 61 provided at an uppermost position and a lower plate 62 positioned under the upper plate 61, both being made of a metal (aluminum, stainless steel or the like). The upper plate 61 and the lower plate 62 are coupled to each other by screws, and a gas diffusion space S is formed therebetween. Moreover, a middle plate 63 made of a metal (aluminum, stainless steel or the like) is provided between the upper plate 61 and the lower plate 62 so that the diffusion space S is divided into a first diffusion space S1, i.e., the upper space, and a second diffusion space S2, i.e., the lower space.

The middle plate 63 serves as a gas diffusion plate. Further, a cover member 64 made of insulating ceramic such as quartz, Y₂O₃ or the like is attached to an entire bottom surface of the lower plate 62 in order to prevent metal contamination and protect the lower plate 62 made of a metal of the like from plasma and damage. A plurality of gas through holes 66 are formed in the lower plate 62. Further, a plurality of gas injection openings 67 are formed in the cover member 64 to correspond to the gas through holes 66. Furthermore, a plurality of gas through holes 68 are formed in the middle plate 63.

A plurality of cylindrical thermally conductive members 70a and 70b for transferring heat applied from the plasma or the like upward are provided in the second diffusion space S2 between the lower plate 62 and the middle plate 63 and in the first diffusion space S1 between the middle plate 63 and the upper plate 61, respectively. The thermally conductive members 70a and 70b are positioned to correspond to each other. The heat from the plasma is emitted to the upper plate 61 via the lower plate 62 and the thermally conductive members 70a and 70b, and then is transferred to the outside from an upper wall of the chamber 1. That is, the corresponding thermally conductive members 70a and 70b are integrated with each other to function as a thermally conductive member for connecting the upper plate 61 and lower plate 62.

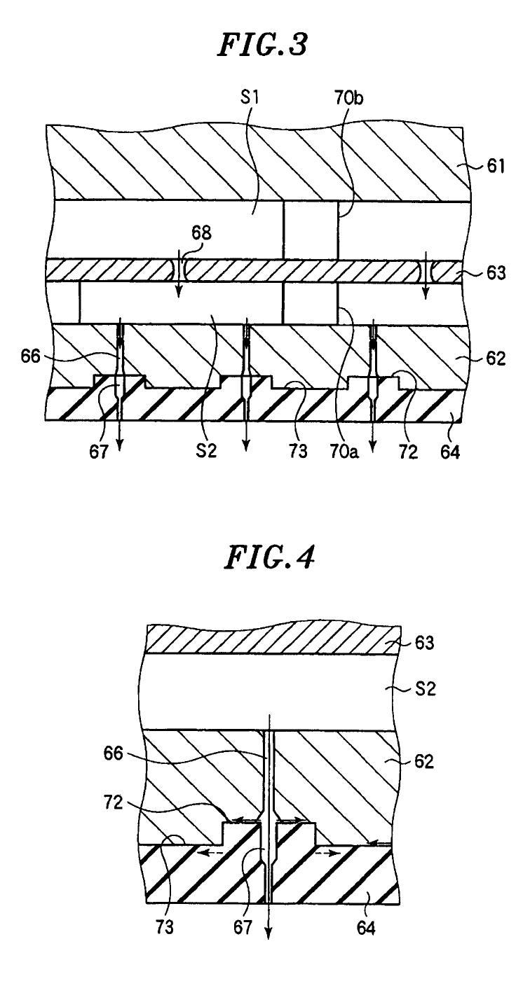

As illustrated in a further enlarged view in FIG. 3, a plurality of convex portions 72 are formed at a top surface of the cover member 64, and concave portions 73 are formed in the bottom surface of the lower plate 62 to correspond to the convex portions 72. The convex portions 72 and the concave portions 73 are engaged with each other, and are positioned to correspond to the gas through holes 66 and the gas injection openings 67, respectively. By providing such a convexoconcave shape, a gas leakage path is bent, as shown in FIG. 4. As a consequence, a conductance of the gas leakage path is decreased and, thus, a gas leakage can be reduced. Moreover, it is possible to decrease the mixture of a leaked gas with one from the adjacent gas leakage path. The effect of reducing the gas leakage can be enhanced by supplying an inert gas between the cover member 64 and the lower plate 62.

The gas injection openings 67 formed in the cover member 64 have a two stage structure, in which a diameter of a lower portion is smaller than that of an upper portion, whereby the conductance of the diffusion space S is greater than the injection conductance. Accordingly, the mixing and the diffusion of the gas in the diffusion space S can be uniformly carried out.

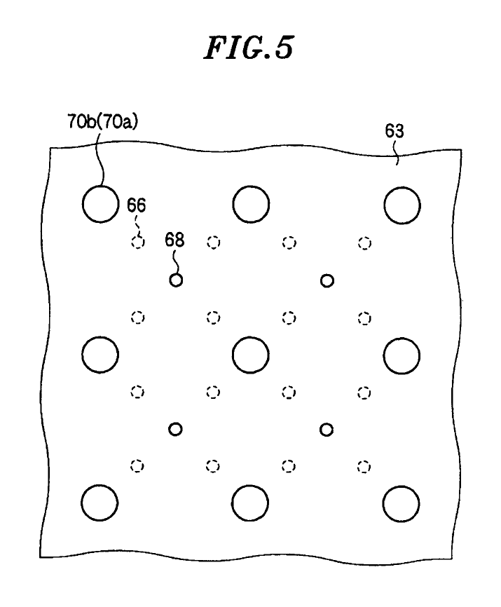

As can be seen from FIG. 5, the thermally conductive member 70a (70b), the gas through holes 68 of the middle plate 63 and the gas through holes 66 of the lower plate 62 are formed in a matrix shape, and the gas through holes 68 and 66 are arranged not to correspond to each other. Further, the thermally conductive member 70a (70b) is positioned so as not to be overlapped with the gas through holes 68 and 66.

A diameter of the thermally conductive members 70a and 70b is in a range of, e.g., about 5 to 20 mm, preferably, about 5 to 12 mm. Further, a distance between adjacent thermally conductive members 70a and 70b is in a range of, e.g., about 7 to 40 mm, preferably, about 9 to 18 mm. Furthermore, it is preferable that the thermally conductive members 70a and 70b are disposed so that a ratio of a cross sectional area of the thermally conductive members 70a to that of the second space S2 and a ratio of a cross sectional area of the thermally conductive members 70b to that of the first space S1 range from about 0.05 to 0.50. When the area ratio is smaller than about 0.05, the heat transfer effect of the thermally conductive members 70a and 70b is insufficient. On the contrary, when it is greater than about 0.50, a flow resistance in the first and the second diffusion space S1 and S2 increases, which may lead to a non-uniform gas flow. Further, the thermally conductive members 70a and 70b may have various cross sectionnal shapes other than a cylindrical shape.

A gas inlet hole 61a is formed at a center of the upper plate 61 to correspond to the gas inlet hole 1b. The processing gas supplied from the processing gas supply unit 15 via the gas supply line 15a and the gas inlet hole 1b is introduced into the shower head 18 through the gas inlet hole 61a. Next, the processing gas is injected from the gas injection openings 67 to the plasma generation region R via the first diffusion space S1, the gas through holes 68 of the middle plate 63, the second diffusion space S2 and the gas through holes 66.

Hereinafter, the processing operation of the plasma etching apparatus configured as described above will be explained.

First of all, the wafer W having an etching target layer is loaded into the chamber 1 by a transfer arm (not shown) by opening the gate valve 24 of the plasma etching apparatus 100 to be mounted on the supporting table 2. Next, the transfer arm is retreated, and the gate valve 24 is closed. Thereafter, the inside of the chamber 1 is exhausted to be a predetermined vacuum level via the gas exhaust line 19 by operating the vacuum pump of the gas exhaust unit 20.

Then, the processing gas for etching is supplied at a predetermined flow rate from the processing gas supply unit 15 into the chamber 1 through the shower head 18. Then, the pressure inside the chamber 1 is maintained at a predetermined level, e.g., about 0.13 to 133.3 Pa (e.g., 1 to 1000 mTorr). In that state, a high frequency power for plasma generation of which frequency is about 40 MHz or higher, e.g., about 100 MHz, is supplied from the high frequency power supply 10a to the supporting table 2. Further, a high frequency power for ion attraction of which high frequency is in a range from about 500 kHz to 27 MHz, e.g., 13.56 MHz, is supplied from the high frequency power supply 10b to the supporting table 2. Furthermore, a predetermined voltage is applied from the DC power supply 13 to the electrode 6a of the electrostatic chuck 6, so that the wafer W is electrostatically attracted by, e.g., a Coulomb force.

By applying a high frequency power to the supporting table 2 as the lower electrode, a high frequency electric field is formed in a processing space between the shower head 18 as the upper electrode and the supporting table 2 as the lower electrode. As a consequence, the processing gas supplied in the processing space is converted into a plasma, and the etching target layer formed on the wafer W is etched by the plasma thus generated.

During the etching, a magnetic field is formed around the processing space by the ring-shaped magnets 21a and 21b in multi-pole state. Accordingly, a suitable effect of confining the plasma is obtained and, thus, the uniformity of the plasma can be improved. Meanwhile, the effect of the magnetic field may not be obtained depending on films. In that case, the processing can be performed while preventing a magnetic field from being formed around the processing space by rotating the segment magnets. In case the magnetic field is formed, even a focus ring region functions as the lower electrode due to the conductive focus ring 5 disposed around the wafer W on the supporting table 2. Accordingly, the plasma generation region is extended to a region above the focus ring 5. As a result, the plasma processing in the peripheral portion of the wafer W is facilitated, thereby improving the uniformity of an etching rate.

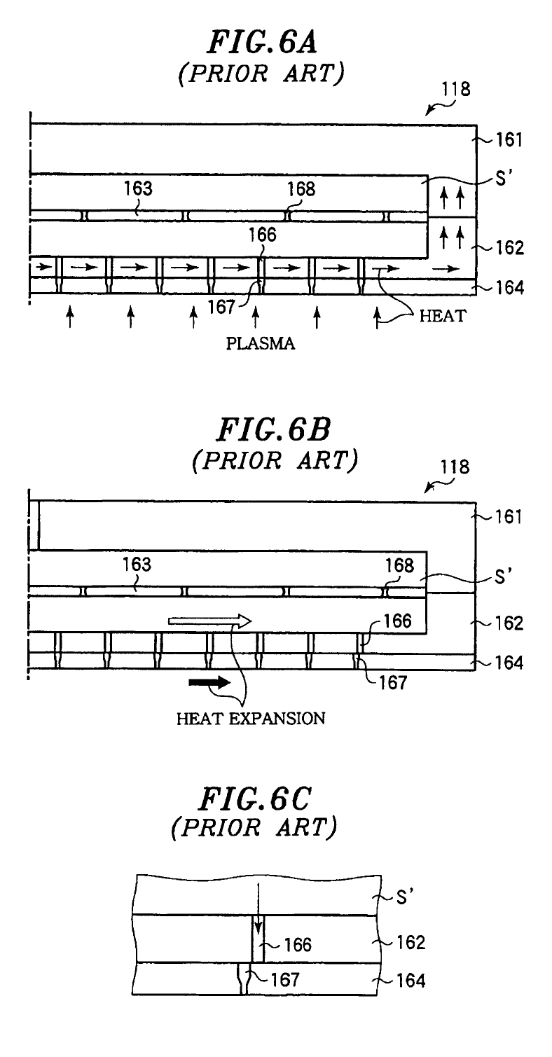

When the plasma etching process is performed in the above manner, the bottom surface of the shower head 18 is heated by heat from the plasma or the like and, thus, the temperature of the shower head 18 increases. In that case, in the conventional shower head, the heat applied from the plasma or the like to the lower plate 162 and the cover member 164 made of ceramic is insulated by an internal space S′, so that the heat is transferred only to the peripheral portion where the upper plate 161 and the lower plate 162 contact with each other to be emitted therefrom, as illustrated in FIG. 6A. Accordingly, the temperatures of the lower plate 162 and the cover member 164 hardly decrease. Further, the heat of the lower plate 162 and the cover member 164 is horizontally transferred from the central portion to the peripheral portion, thereby forming a horizontal temperature gradient.

Meanwhile, the lower plate 162 is made of a metal such as aluminum or stainless steel and thus has a large thermal expansion coefficient. The cover member 164 is made of insulating ceramic such as quartz, Y₂O₃ or the like which has a smaller thermal expansion coefficient than that of the metal. Thus, if the temperature increases to, e.g., about 140° C., in a state where the lower plate 162 and the cover member 164 are adjacent to each other, and also if the horizontal temperature gradient is formed as described above, the gas through holes 166 of the lower plate 162 and the gas injection holes 167 of the cover member 164 are misaligned in the peripheral portion due to the thermal expansion difference therebetween, as can be seen from FIG. 6B.

In that case, as illustrated in FIG. 6C, the gas injection openings 167 and the gas through holes 166 are completely misaligned in the peripheral portion, which may completely block the gas injection. This is because the gas injection openings 167 are formed in a small diameter for the purpose of preventing metal contamination or abnormal discharge due to plasma infiltration. Since the gas injection amount in the peripheral portion affects etching selectivity, the significant reduction of the gas injection amount in the peripheral portion deteriorates the etching characteristics.

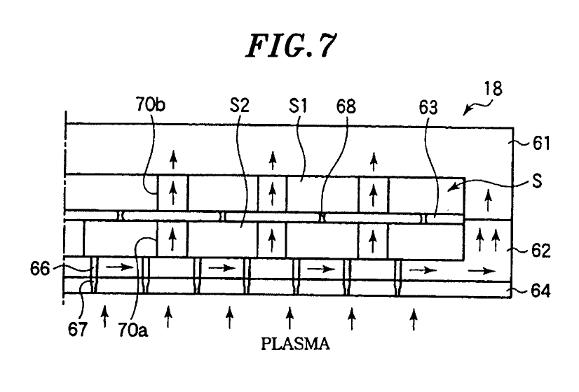

On the other hand, in the present embodiment, the thermally conductive members 70a and 70b are provided in the gas diffusion space S of the shower head 18, and the heat is transferred upwardly from the cover member 64 and the lower plate 62 to the upper plate 61 via the thermally conductive members 70a and 70b, as depicted in FIG. 7. Hence, the heat applied from the plasma or the like to the cover member 64 and the lower plate 62 can be quickly and uniformly transferred to the upper plate 61 via the thermally conductive members 70a and 70b to be emitted to the outside. Consequently, the temperature increase is suppressed, and the horizontal temperature gradient hardly occurs. Accordingly, the thermal expansion difference is hardly generated between the metal lower plate 62 and the ceramic cover member 64 and, also, the misalignment of the gas through holes 66 and the gas injection openings 67 in the peripheral portion of those plates 62 and 64 can be suppressed. As a result, the deterioration of the etching characteristics can be minimized.

Moreover, even if the thermally conductive members are provided in the gas diffusion space S, the gas conductance of the horizontal direction is substantially not affected as long as the area ratio of the thermally conductive members to the diffusion space S is within a desired range from about 0.05 to 0.5. In that case, the difference of the gas injection amount between the central portion and the peripheral portion is only about 2%, so that the etching characteristics are not affected.

In addition, the convex portions 72 are formed at the top surface of the cover member 64, and the concave portions 73 are formed in the bottom surface of the lower plate 62. Since the convex portions 72 are engaged with the concave portions 73, the gas leakage path where the processing gas leaks between the lower plate 62 and the cover member 64 is bent. Accordingly, the conductance of the gas leakage path is decreased, thereby reducing the gas leakage.

As set forth above, the heat applied from the plasma to the lower plate 62 and the cover member 64 can be quickly and uniformly transferred upward by the presence of the thermally conductive members 70a and 70b and, thus, the misalignment of the gas injection openings can be suppressed. Such an effect can be further enhanced by providing to the upper plate 61 a forcible cooling medium such as fins, a fan, a coolant supply unit or the like. Further, by providing a heating unit or a cooling unit to the upper plate 61, an effect of controlling the temperature of the shower head 18 can be achieved.

The present invention can be variously modified without being limited to the above embodiment. For example, in the above embodiment, the cover member formed as a plate is attached to the entire surface of the lower plate. However, a film made of ceramic can be coated thereon without being limited to the above example. Although the middle plate is provided in the above embodiment, thermally conductive members can directly connect the lower plate with the upper plate without providing the middle plate.

Moreover, in the above embodiment, the present invention is applied to the capacitively coupled parallel plate plasma etching apparatus. However, the present invention is not limited thereto, and can be applied to an apparatus for performing a processing using another plasma source, e.g., a microwave plasma processing or the like, an apparatus for performing another plasma processing, e.g., plasma CVD or the like other than etching, or an apparatus for performing a processing which does not use a plasma, e.g., thermal CVD or the like. In addition, although a semiconductor wafer is used as an example of a substrate to be processed in the above embodiment, the substrate to be processed is not limited thereto, and can be another substrate such as a glass substrate for use in a flat panel display (FPD) represented by a liquid crystal display (LCD) or the like.

While the invention has been shown and described with respect to the embodiments, it will be understood by those skilled in the art that various changes and modification may be made without departing from the scope of the invention as defined in the following claims.

What is claimed is:

1. A substrate processing apparatus comprising:
a processing chamber accommodating therein a substrate to be processed;
a mounting table disposed in the processing chamber, for mounting thereon the substrate to be processed;
a shower head provided opposite to the mounting table, for injecting a processing gas into the processing chamber;
a gas exhaust unit for exhausting an inside of the processing chamber; and
a processing unit for performing a predetermined processing on the substrate to be processed in the processing chamber,
wherein the shower head includes:
an upper plate made of a metal and having a gas inlet hole;
a lower plate made of a metal and having a plurality of gas through holes;
a gas diffusion space formed between the upper plate and the lower plate;
a cover member made of ceramic and having a plurality of gas injection openings positioned to correspond to the gas through holes, for covering a bottom surface of the lower plate; and
a plurality of thermally conductive members provided to connect the upper plate with the lower plate in the gas diffusion space, for transferring heat generated by the processing of the processing unit upward.

2. A substrate processing apparatus comprising:
a processing chamber accommodating therein a substrate to be processed;
a mounting table disposed in the processing chamber, for mounting thereon the substrate to be processed;
a shower head provided at opposite to the mounting table, for injecting a processing gas into the processing chamber;
a gas exhaust unit for exhausting an inside of the processing chamber; and
a processing unit for performing a predetermined processing on the substrate to be processed in the processing chamber,
wherein the shower head includes:
an upper plate made of a metal and having a gas inlet hole;
a lower plate made of a metal and having a plurality of gas through holes;
a middle plate provided between the upper plate and the lower plate and having a plurality of gas through holes;
a first gas diffusion space provided between the upper plate and the middle plate;
a second gas diffusion space provided between the middle plate and the lower plate;
a cover member made of ceramic and having a plurality of gas injection openings positioned to correspond to the gas through holes, for covering a bottom surface of the lower plate; and
a plurality of thermally conductive members provided to connect the upper plate with the middle plate in the first gas diffusion space and to connect the middle plate with the lower plate in the second gas diffusion space, for transferring heat generated by the processing of the processing unit upward.

3. The substrate processing apparatus of claim 2, wherein the thermally conductive members provided in the first gas diffusion space and the thermally conductive members provided in the second diffusion space are arranged to correspond to each other.

4. The substrate processing apparatus of claim 1 or 2, wherein the processing unit performs plasma processing on the substrate to be processed by generating a plasma in the processing chamber.

5. The substrate processing apparatus of claim 4, wherein the processing unit forms a high frequency electric field between the mounting table and the shower head, and a plasma is generated by the high frequency electric field.

6. The substrate processing unit of claim 1 or 2, wherein a contact portion between the lower plate and the cover member is formed in a convexoconcave shape.

7. The substrate processing apparatus of claim 1 or 2, wherein the thermally conductive members have a cylindrical shape.

8. The substrate processing apparatus of claim 1 or 2, wherein the thermally conductive members have a diameter in a range from about 2 to 12 mm.

9. The substrate processing apparatus of claim 1 or 2, wherein the shower head further includes a cooling unit for forcibly emitting heat transferred via the thermally conductive members.

10. A shower head provided opposite to a mounting table which mounts thereon a substrate to be processed in a processing chamber, for injecting a processing gas into the processing chamber, the shower head comprising:
an upper plate made of a metal and having a gas inlet hole;
a lower plate made of a metal and having a plurality of gas through holes;
a gas diffusion space formed between the upper plate and the lower plate;
a cover member made of ceramic and having a plurality of gas injection openings positioned to correspond to the gas through holes, for covering a bottom surface of the lower plate; and
a plurality of thermally conductive members provided to connect the upper plate with the lower plate in the gas diffusion space, for transferring heat generated by processing performed in the processing chamber upward.

11. A shower head provided opposite to a mounting table which mounts thereon a substrate to be processed in a processing chamber, for injecting a processing gas when performing a predetermined processing in the processing chamber, the shower head comprising:
an upper plate made of a metal and having a gas inlet hole;
a lower plate made of a metal and having a plurality of gas through holes;
a middle plate provided between the upper plate and the lower plate, having a plurality of gas through holes;
a first gas diffusion space provided between the upper plate and the lower plate;
a second gas diffusion space provided between the middle plate and the lower plate;
a cover member made of ceramic and having a plurality of gas injection openings positioned to correspond to the gas through holes, for covering a bottom surface of the lower plate; and
a plurality of thermally conductive members provided to connect the upper plate with the middle plate in the first gas diffusion space and to connect the middle plate with the lower plate in the second gas diffusion space, for transferring heat generated by the processing performed in the processing chamber upward.

12. The shower head of claim 11, wherein the thermally conductive members provided in the first gas diffusion space and the thermally conductive members provided in the second diffusion space are arranged to correspond to each other.

13. The shower head of claim 10 or 11, wherein the processing is plasma processing which is performed on a substrate to be processed by generating a plasma in the processing chamber.

14. The shower head of claim 10 or 11, wherein a contact portion between the lower plate and the cover member is formed in a convexoconcave shape.

15. The shower head of claim 10 or 11, wherein the thermally conductive members have a cylindrical shape.

16. The shower head of claim 10 or 11, wherein the thermally conductive members have a diameter in a rage from about 2 to 12 mm.

17. The shower head of claim 10 or 11, wherein the shower head further includes a cooling unit for forcibly emitting heat transferred via the thermally conductive members.
